(19) United States
(12) Patent Application Publication
(10) Pub. No.: US 2014/0342104 A1
(43) Pub. Date: Nov. 20, 2014

(54) AG ALLOY FILM FOR REFLECTIVE ELECTRODES, AND REFLECTIVE ELECTRODE

(71) Applicant: KABUSHIKI KAISHA KOBE SEIKO SHO (KOBE STEEL, LTD.), Kobe-shi, Hyogo (JP)

(72) Inventors: Yuki Tauchi, Kobe-shi (JP); Yoko Shida, Kobe-shi (JP)

(73) Assignee: KABUSHIKI KAISHA KOBE SEIKO SHO (KOBE STEEL, LTD.), Kobe-shi, Hyogo (JP)

(21) Appl. No.: 14/362,773

(22) PCT Filed: Dec. 19, 2012
(86) PCT No.: PCT/JP2012/082966

§ 371 Date: Jun. 4, 2014

(30) Foreign Application Priority Data
Dec. 27, 2011 (JP) 2011-285922

(51) Int. Cl. G02B 5/08; C22C 5/06; G02F 1/1343; H01B 13/00; H01B 1/08; C23C 14/18

(52) U.S. Cl. CPC G02B 5/0808; H01B 1/08; C23C 14/185; G02F 1/13439; H01B 13/0026; C22C 5/06
USPC 428/1.4; 428/336; 204/192.17; 428/457; 428/606; 420/501; 420/506

(57) ABSTRACT

An Ag alloy film for use in reflective electrodes is provided, which has a low electrical resistivity and a high reflectance that are almost at the same levels as those of an Ag film, and has excellent oxidation resistance. An Ag alloy film for reflective electrodes, which can be used in a reflective electrode and is characterized in that at least one element selected from the group consisting of In and Zn is contained in an amount of 0.1 to 2.0 atomic %.

### TECHNICAL FIELD

The present invention relates particularly to a reflective electrode and an Ag alloy film for use in reflective electrodes. The present invention relates to an Ag alloy film for use in a reflective electrode, having low electrical resistivity and high reflectance, that are almost at the same levels as those of an Ag film, and oxidation resistance superior to the Ag film, and a reflective electrode comprising the Ag alloy film, an Ag alloy sputtering target for use in deposition of the Ag alloy film, and a liquid crystal display or the like having a device which comprises the reflective electrode.

The reflective electrode according to the present invention includes an interconnection consisting of a film which comprises the reflective electrode.

### BACKGROUND ART

Since an Ag film of certain thickness or larger has high reflectance in visible light and low electrical resistance, it is expected to applicable to a reflective electrode and an interconnection film of a liquid crystal display device, an organic EL display device, or the like.

The Ag film, however, is readily deteriorated at high temperature. It thus has a problem of degradation in the high reflectance and the low electrical resistance when the film is subjected to a thermal hysteresis in the course of manufacturing process of the display device. Various technologies have been proposed by taking the problem regarding the Ag film into consideration.

Patent Document 1, for example, discloses an Ag alloy film containing one or two kinds of element selected from the group consisting of Bi and Sb in a total amount of 0.01 to 4 atomic %, which has high reflectance inherent in Ag and circumvents degradation of the reflectance with time by suppressing agglomeration and crystal grain growth. Patent Document 2 discloses an Ag based alloy film constituting a reflective anode electrode in an organic EL display device. It is demonstrated by adding 0.01 to 1.5 atomic % of Nd or 0.01 to 4 atomic % of Bi to the Ag based alloy film that the dark spot phenomenon in an organic EL display device can be successfully circumvented by exertion of the effect of the elements to prevent agglomeration of Ag.

Patent Document 3 discloses that high reflectance can be achieved by adding Bi to Ag to suppress crystal grain growth and agglomeration in an Ag film as well as by further adding V, Ge, and Zn within a range which satisfies a predetermined expression.

### PRIOR ART REFERENCES

### Patent Documents

Patent Document 1: Japanese Patent Application Publication No. 2004-126497

Patent Document 2: Japanese Patent Application Publication No. 2010-225586

Patent Document 3: International Patent Application Publication No. 2009/041529

### SUMMARY OF THE INVENTION

### Problems to be Solved by the Invention

The Ag film is generally subjected to a cleaning treatment such as an UV irradiation or an O₂ plasma treatment after deposition in the manufacturing process of the display panel. The treatment, however, causes a problem of oxidation and blackening Ag. The blackening is induced by chemical reaction of Ag with reactive oxygen radicals produced in the course of the UV or O₂ plasma irradiation.

Particularly in a top-emission type OLED display panel in which the light is emitted from the opposite side of the substrate, an organic material layer is laminated on top of a reflective electrode consisting of a single layer Ag film or a reflective electrode comprising an Ag film. For the purpose of securing electrical connection of the reflective electrode with the organic material, the surface of the reflective electrode is always cleaned by being subjected to the treatment such as an UV irradiation or an O₂ plasma treatment prior to the deposition of the organic material in the course of the manufacturing process of the display panel. In order to suppress deterioration of the reflective electrode, specifically the blackening of Ag film by oxidation, a means to protect the Ag film is employed by depositing either a transparent conductive oxide film such as ITO or an oxide film either directly above or directly beneath the Ag film. Even if the ITO or the like is deposited, there is a case in which the Ag film is incompletely protected and deteriorated due to various causes such as non-uniformity in thickness or presence of pinholes in the ITO film or the like. It is thus required for the Ag film itself to have excellent resistance to the cleaning treatment (hereinafter referred to as oxidation resistance).

It is required for the Ag based film to have low electrical resistivity and high reflectance which are necessary for a reflective electrode or a reflective interconnection as well as to have excellent oxidation resistance. Previously proposed Ag alloy films of various kinds cannot fulfill all of the characteristics.

The present invention has been made in light of the circumstances described above. It is a particular object of the present invention to realize an Ag alloy film for use in a reflective electrode, having low electrical resistivity and high reflectance, that are almost at the same levels as those of an Ag film, and oxidation resistance superior to Ag and existing Ag alloy films, and a reflective electrode comprising the Ag alloy film.

### Solution to Problem

The present invention provides an Ag alloy film for a reflective electrode, a reflective electrode, an Ag alloy sputtering target, a liquid crystal display device, an organic EL display device, an organic EL lighting device, an inorganic EL display device, an inorganic EL lighting device, a touch panel device, a projection display device, and a LED device described hereinafter.
(1) An Ag alloy thin film, for use in reflective electrodes, comprising; at least one element selected from the group consisting of In and Zn in an amount of 0.1 to 2.0 atomic %.
(2) The Ag alloy thin film of (1) further comprising Bi in an amount of 0.01 to 1.0 atomic %. However, Ag—Zn—Bi alloy film which contains only Zn among the group of In and Zn and satisfies the following expression (1) is excluded;

7×[A]+13×[Bi]≧8 (1)
In the expression (1), [A] denotes content of Zn in atomic % and [Bi] denotes content of Bi in atomic %.
(3) A reflective electrode comprising;
   the Ag alloy film of (1) or (2),
   a transparent conductive film consisting of ITO or IZO,
   wherein the transparent conductive film is formed in a thickness range of 5 to 20 nm directly above the Ag alloy film.
(4) An Ag alloy sputtering target, for use in depositing the Ag alloy film of (1) or (2), comprising at least one element selected from the group consisting of In and Zn in an amount of 0.1 to 2.0 atomic %.
(5) The Ag alloy sputtering target of (4) further comprising Bi in an amount of 0.01 to 1.0 atomic %. However, Ag—Zn—Bi alloy sputtering target which contains only Zn among the group of In and Zn and satisfies the following expression (1) is excluded;

7×[A]+13×[Bi]≧8 (1)
In the expression (1), [A] denotes content of Zn in atomic % and [Bi] denotes content of Bi in atomic %.
(6) A liquid crystal display device, comprising the reflective electrode of (3).
(7) An organic EL display device or an organic EL lighting device, comprising the reflective electrode of (3).
(8) An inorganic EL display device or an inorganic EL lighting device, comprising the reflective electrode of (3).
(9) A touch panel device, comprising the reflective electrode of (3).
(10) A projection display device, comprising the reflective electrode of (3).
(11) A LED device, comprising the reflective electrode of (3).

### Advantageous Effects of Invention

According to the present invention, an Ag alloy film having low electrical resistivity and high reflectance that are almost at the same levels as those of an Ag film, and oxidation resistance superior to Ag and existing Ag alloy films is obtained. Therefore, by applying the Ag alloy film of the present invention to a reflective electrode, superior display performance can be attained in the top-emission type OLED display panel as the Ag alloy film shows unique resistance to oxidation treatment such as UV irradiation.

### BRIEF DESCRIPTION OF DRAWINGS

FIG. 1 shows an optical microscope image (magnification: ×50) of the surface of the laminated film of Example No. 1 after the UV treatment.

### DESCRIPTION OF EMBODIMENTS

As described above, intensively pursued by the present inventors was an Ag alloy film for use in a reflective electrode, having low electrical resistivity and high reflectance that are almost at the same levels as those of an Ag film, and superior oxidation resistance, even if the Ag alloy film is applied to a reflective electrode of a display device which is manufactured by a process comprising a cleaning treatment step such as UV irradiation after the formation of the reflective electrode. It was found In and Zn are, among various kinds of alloy elements constituting the Ag alloy, remarkably effective to realize to secure all of the low electrical resistivity and the high reflectance that are almost at the same levels as those of an Ag film, and, and the superior oxidation resistance. The present invention has thus been accomplished.

In order to secure the effect, each of In and Zn is to be solely contained or both of the elements are to be contained. The amount (if more than one kind of element are contained, the amount means total amount hereinbelow) is to be controlled to 0.1 atomic % or more, preferably 0.3 atomic % or more, and more preferably 0.5 atomic % or more. On the contrary, addition of excessive amount of In or Zn tends to increase the electrical resistivity or decrease the reflectance. The amount of In or Zn is thus controlled to 2.0 atomic % or less in the present invention. It is preferably 1.5 atomic % or less, and more preferably 1.3 atomic % or less. It is even more preferably 1.0 atomic % or less from a view point of obtaining lower electrical resistivity and higher reflectance.

The content of the Ag alloy film of the present invention is as described above, and the balance being Ag and inevitable impurities (for example, Si, Fe, C, O (oxygen) of 0.01 weight % or less). The oxidation resistance of the Ag alloy may be improved by further adding Bi.

In order to exert the effect of Bi, it is preferred for the Ag alloy to contain Bi in an amount of 0.01 atomic % or more. The content of Bi is more preferably 0.05 atomic % or more. On the other hand, the content of Bi is preferably controlled to 1.0 atomic % or less because excessive content of Bi in the Ag alloy results in increase of electrical resistivity and decrease of reflectance as for the case in which In or the like is contained. The content of Bi is more preferably 0.8 atomic % or less, and even more preferably 0.5 atomic % or less.

In contrast to the technology disclosed in Patent Document 3, the present invention is characterized in that, among various alloy elements, In and/or Zn must be contained in order to satisfy all the characteristics such as the oxidation resistance. The invention of Patent Document 3 is related to a technology to mainly improve reflectance. There is no indication to improve resistance to the UV irradiation and the O₂ plasma treatment, nor any disclosure that Bi is remarkably effective in the Patent Document. Therefore, for the purpose of avoiding overlapping of the present invention and that of Patent Document 3, Ag—Zn—Bi alloy film which contains only Zn among the group of In and Zn and satisfies the following expression (1) is excluded;

7×[A]+13×[Bi]≧8 (1)

In the expression (1), [A] denotes content of Zn in atomic % and [Bi] denotes content of Bi in atomic %.

It is preferred that the thickness of the Ag alloy film is in a range from 30 to 200 nm. High reflectance and nearly zero transparency can be secured by controlling the thickness of the Ag alloy film to 30 nm or more. The thickness is more preferably 50 nm or more. On the other hand, excessive thickness in the Ag alloy film causes delamination of a film formed on the reflective electrode and decrease in productivity due to prolonged period of deposition of the Ag alloy film. The thickness of the Ag alloy film is thus preferably 200 nm or less, and more preferably 150 nm or less.

The Ag alloy film is preferably formed by a sputtering method with a sputtering target. This is because the sputtering method is excellent in terms of ease of alloying, productivity, and in-plane uniformity in thickness, and preferred among various methods to deposit a thin film such as inkjet coating method, vacuum evaporation method, and sputtering method.

In the case where the Ag alloy film is formed by the sputtering method, an Ag alloy sputtering target containing at least one element selected from the group consisting of In and Zn in an amount of 0.1 to 2.0 atomic % and having a composition the same as the composition of a desired Ag alloy film is suitably used because the use of such a sputtering target eliminates composition deviation and results in the formation of an Al alloy film having an intended composition.

A sputtering target further containing Bi in an amount of 0.01 to 1.0 atomic % may be suitably used to form a Ag alloy film further containing Bi. It should be noted here that an Ag—Zn—Bi alloy sputtering target which contains only Zn among the group of In and Zn and satisfies the following expression (1) is excluded;

7×[A]+13×[Bi]≧8 (1)

In the expression (1), [A] denotes content of Zn in atomic % and [Bi] denotes content of Bi in atomic %.

Examples of a method for producing the target include a vacuum melt-casting method and a powder sintering method. The vacuum melt-casting method is preferred from a view point of securing in-plane uniformity in composition and texture of target.

A substrate used for the present invention is not particularly limited. Examples of such substrate are glass, resin such as PET (polyethylene terephthalate), or the like.

The present invention includes a reflective electrode comprising the Ag alloy film formed on the substrate, and a transparent conductive film, preferably ITO or IZO, formed directly above the Ag alloy film on the opposite side of the substrate. The Ag alloy film reflective electrode may be formed not only directly above the substrate but also indirectly through a TFT or a transparent conductive film such as ITO or the like as a base layer. The deposition method of the transparent conductive film is not particularly limited. The transparent conductive film may be deposited by a general method such as a sputtering method.

The transparent conductive film may have a normal range of thickness. The thickness may be 5 nm or more, and preferably 7 nm or more. It may be 20 nm or less, and preferably 15 nm or less.

The Ag alloy film may be subjected to a heat treatment (post-annealing) after the formation of the transparent conductive film. The temperature of the post-annealing is preferably 200° C. or more, and more preferably 250° C. or more. It is preferably 350° C. or less, and more preferably 300° C. or less. The duration of the post-annealing is preferably about 10 minutes or more, and more preferably about 15 minutes or more. It is preferably about 120 minutes or less, and more preferably about 60 minutes or less.

The Ag alloy film according to the present invention satisfies the property of electrical resistivity of 6.0 μΩcm or less. The electrical resistivity is preferably 5.0 μΩcm or less, more preferably 4.5 μΩcm or less, and even more preferably 4.0 μΩcm or less.

The reflectance at 550 nm wavelength of the Ag alloy single layer film of 100 nm or more in thickness is 95.0% or more. The reflectance is preferably 96.0% or more, and more preferably 96.5% or more.

The reflectance at 550 nm wavelength of the laminated film, simulating an example of the reflective electrode, comprising a transparent conductive film such as an ITO film formed directly above the Ag alloy film is 95.0% or more after the heat treatment at 250° C. for 1 hour. The reflectance is preferably 95.5% or more, and more preferably 96.0% or more.

Further, as a measure of superior oxidation resistance, the Ag alloy film according to the present invention has a defect (dark spot) density of 500 or less per a given area of 120 mm×90 mm after the UV irradiation to the laminate comprising the Ag alloy film as described later in Examples. The number of defects per the given area is preferably 350 or less, and more preferably 200 or less. Moreover, the total area of the defects is 5,000 pixels per the given area of 120 mm×90 mm with reference to the area of defects of 11,618 pixels of a pure Ag film. It is preferably 4,600 pixels or less, more preferably 4,000 pixels or less, and even more preferably 3,000 pixels or less.

The reflective electrode according to the present invention (more specifically a device comprising the reflective electrode according to the present invention) is used in, for example, a liquid crystal display device, an organic EL display device such as a top-emission type OLED display panel, an organic EL lighting device, an inorganic EL display device, an inorganic EL lighting device, a touch panel device, a projection display device, and a LED device.

### EXAMPLES

The present invention is more specifically described below by presenting examples. The present invention is not limited to these examples described below. The present invention may be modified and performed without departing from the essence of the present invention described above and below. They are also within the technical scope of the present invention.

On a glass substrate (an alkali-free glass # 1737 manufactured by Corning Inc., diameter: 50 mm, thickness: 0.7 mm) pure Ag or Ag alloy films having various alloy compositions shown in Table 1 were deposited by sputtering method using a DC magnetron sputtering apparatus. The pure Ag and the Ag alloy films are sometimes collectively referred to as Ag alloy films hereinafter. The films were in the form of a single layer of 100 nm in thickness. The deposition condition was as follows.

### Film Deposition Condition

Substrate temperature: room temperature
Sputtering power: 250 W·dc
Ar gas pressure: 1-3 mTorr
Anode—cathode distance: 55 mm
Deposition rate: 7.0-8.0 nm/sec
Base pressure: 1.0×10⁻⁵ Torr or less

A pure Ag target was used to deposit the pure Ag film. Used to deposit the Ag alloy films were Al alloy sputtering targets prepared by a vacuum melt-casting method having the same composition as each of the films or composite targets having metal chips comprising the metal elements shown in Table 1 attached on the sputtering surface of a pure Ag target. The diameter of each of the target was 4 inches.

Electrical resistivity, reflectance at 550 nm wavelength of the Ag alloy single layer film, reflectance at 550 nm wavelength of the Ag alloy films laminated by an ITO film after the heat treatment, and density of defects generated by the UV treatment were measured in the Ag alloy films prepared in the manner described above. The details of the measurement methods are as follows. Chemical compositions of the Ag alloy films used in the examples were quantitatively measured by using an inductively coupled plasma emission spectrometer (ICP-8000 manufactured by Shimadzu Corporation).

### Measurement of Electrical Resistivity

The electrical resistivity of the Ag alloy film was measured by four-point probe method. If the electrical resistivity is 6.0 μΩcm or less, it is evaluated as low electrical resistivity.

### Measurement of Visible Reflectance of Ag Alloy Film at Wavelength of 550 nm

The visible reflectance of the Ag alloy film (single layer film) at wavelength of 550 nm was evaluated by measuring the absolute reflectivity using a spectrophotometer (V-570 spectrophotometer manufactured by JASCO Corp.). If the reflectance is 95.0% or more, it is evaluated as high reflectance.

### Measurement of Visible Reflectance of Laminated Film after Heat Treatment at Wavelength of 550 nm

The reflectance of Ag alloy films which were laminated by an ITO film and subjected to a heat treatment was also measured. More specifically, laminates having a structure of an ITO film of 7 nm in thickness/an Ag alloy film of 100 nm in thickness/a glass substrate were prepared by depositing an ITO film of 7 nm in thickness on the Ag alloy films. The deposition condition of the ITO film was; DC magnetron sputtering using an ITO target, with an inlet gas mixture of about 10% O₂ in Ar, substrate temperature of 25° C., gas pressure of 0.8 mTorr, DC power of 150 W. The laminates were subsequently subjected to a heat treatment in a nitrogen atmosphere of an infrared lamp annealing furnace at 250° C. for 1 hour, simulating a post annealing in the manufacturing process. The laminate film samples were thus prepared. Then the visible reflectance of the laminate film samples was measured at wavelength of 550 nm in the same manner as for the Ag alloy films. If the reflectance is 95.0% or more, it is evaluated as high reflectance.

### Evaluation of Oxidation Resistance to Defect Generation by the UV Treatment

The laminated film samples, simulating a reflective electrode, which were prepared by forming an ITO film on the Ag alloy films and further subjected to the heat treatment, were used for evaluation of the oxidation resistance. The UV treatment was conducted for the laminated film samples under the condition shown below. Number and total area of defects (dark spots generated by oxidation of Ag) were measured in an optical micrograph taken at a magnification of 50 for the laminated films after the UV treatment. Image processing for the measurement was done by using analySIS® manufactured by Soft Imaging System GmbH. If the number of defects generated in the given area of 120 mm×90 mm is 500 or less and the total area of defects is 5,000 pixels or less with reference to the area of defects of 11,618 pixels of a pure Ag film, it is evaluated as superior in terms of oxidation resistance.

### UV Treatment Condition

Low pressure mercury lamp
Central wavelength: 254 nm
UV irradiance: 40 mW/cm²
Irradiation time: 30 min.

The results are shown in Table 1.

TABLE 1

| | | | | Reflectance after | | | |
|---|---|---|---|---|---|---|---|
| | | | | the heat treatment | | | |
| | | Electrical | Reflectance | (Laminated film of | Defects after UV | | |
| | | resistivity | (Single | ITO (7 nm)/Ag (100 nm)/ | treatment | | |
| | | (Single | layer film) | substrate) | Number | | |
| | | layer film) | 550 nm | 550 nm | of defects | Area | |
| No. | Composition (*) | μΩcm | % | % | pieces | pixels | Evaluation |
| 1 | Ag | 2.90 | 97.1876 | 97.777 | 572 | 11618 | Fail |
| 2 | Ag—0.8Zn | 4.30 | 96.9224 | 97.1284 | 97 | 2036 | Pass |
| 3 | Ag—1.1Zn | 4.80 | 96.6525 | 97.2065 | 175 | 2337 | Pass |
| 4 | Ag—1.3Zn | 5.00 | 96.5058 | 96.9913 | 181 | 2293 | Pass |
| 5 | Ag—2.1Zn | 6.30 | 96.1862 | 96.5804 | 231 | 3901 | Fail |
| 6 | Ag—3.2Zn | 6.60 | 95.921 | 94.4851 | 60 | 1078 | Fail |
| 7 | Ag—4.2Zn | 8.20 | 95.2756 | 93.6254 | 78 | 1223 | Fail |
| 8 | Ag—0.1Bi—1.6Zn | 5.50 | 96.4748 | 96.5937 | 166 | 2760 | Pass |
| 9 | Ag—0.5In | 4.20 | 97.0195 | 97.0055 | 136 | 3548 | Pass |
| 10 | Ag—1.1In | 5.80 | 96.3542 | 96.0365 | 304 | 4544 | Pass |
| 11 | Ag—2.1In | 8.00 | 95.2345 | 95.0965 | 80 | 1961 | Fail |
| 12 | Ag—2.8In | 9.80 | 94.1361 | 93.7729 | 46 | 1488 | Fail |
| 13 | Ag—4.0In | 8.88 | 93.2254 | 93.0373 | 41 | 772 | Fail |
| 14 | Ag—5.31n | 10.45 | 92.592 | 92.7372 | 309 | 5482 | Fail |
| 15 | Ag—0.1Bi—2.3In | 8.50 | 94.217 | 94.3843 | 28 | 1298 | Fail |
| 16 | Ag—1.0Ge | 6.41 | 96.2175 | 94.6396 | 200 | 3860 | Fail |
| 17 | Ag—2Ge | 10.04 | 94.8017 | 92.8449 | 157 | 4139 | Fail |
| 18 | Ag—3.4Ge | 14.81 | 93.1262 | 90.4924 | 178 | 5218 | Fail |
| 19 | Ag—1.0Cu | 3.58 | 97.287 | 95.9171 | 267 | 7769 | Fail |
| 20 | Ag—3.0Cu | 4.13 | 96.6846 | 94.97 | 5 | 184 | Fail |
| 21 | Ag—6.4Cu | 4.64 | 96.4939 | 94.8351 | 5 | 179 | Fail |
| 22 | Ag—0.5Bi—0.5Ge | 3.40 | 95.6652 | 95.8427 | 568 | 13522 | Fail |
| 23 | Ag—0.5Bi—0.5Ge—0.5Cu | 3.80 | 94.3697 | 94.9323 | 348 | 6755 | Fail |

(*) The numerial values in this column represent atomic %.

The results shown in Table 1 can be considered as follows. The Ag alloy films of Nos. 2-4 and 8-10, comprising predetermined amount of either or both of In and Zn, show low electrical resistivity and high reflectance in the form of the single layer film immediately after its formation. The Ag alloy films laminated by ITO film also show high reflectance after the heat treatment. Further, the Ag alloy films are superior in oxidation resistance as the defect generation by the UV treatment is suppressed.

Particularly, by comparing example No. 2 or No. 9 with No. 1 (an Ag film), it is evident that the oxidation resistance can be remarkably enhanced without deteriorating the electrical resistivity and reflectance by adding small amount of In or Zn to Ag.

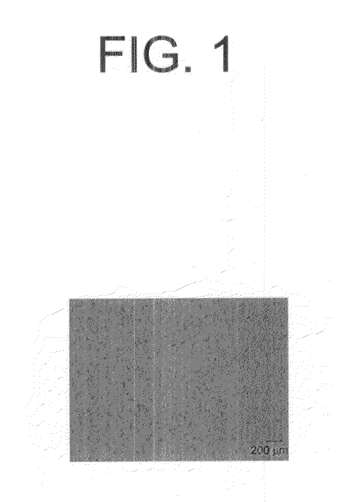

The Ag film of example No. 1, on the other hand, is significantly inferior in terms of oxidation resistance although the reflectance is high in the form of a single layer film and a laminated film, and the resistivity is sufficiently low. An optical microscope image of the surface of the stacked layer after the UV treatment is shown in FIG. 1 for the reference. Many dark defects generated by the oxidation of Ag are observed on the surface of Ag film as shown in FIG. 1.

As shown by examples Nos. 5 to 7 and 11 to 15, the electrical resistivity decently tends to increase and the reflectance tends to decrease by adding excessive amount of In or Zn to Ag.

Further, as demonstrated by examples Nos. 16 to 23, if alloying element is other than In or Zn, the Ag alloy films fail to satisfy all of the required properties of low electrical resistivity, high reflectance, and high oxidation resistance as they did not show either low electrical resistivity or high reflectance or high oxidation resistance.

As demonstrated by examples Nos. 16 to 18, if Ge is added, the Ag alloy films fail to secure the low electrical resistivity and high reflectance. Further, if the amount of Ge is high, the oxidation resistance is deteriorated. The Ag alloy films thus fail to secure all of the required properties.

As demonstrated by examples Nos. 19 to 21, if Cu is added, the oxidation resistance is deteriorated or the reflectance of the laminated film is lowered.

As demonstrated by example No. 22, if both Ge and Bi are contained, the oxidation resistance is significantly deteriorated. Further, as demonstrated by example No. 23, the oxidation resistance is not secured and the reflectance of the Ag alloy of the single layer and laminated films is lowered if various elements other than those specified in the present application.

There are examples such as Nos. 2 to 4 in which the reflectance of Ag alloy film is lower in a form of single layer as compared to those laminated by an ITO film and being subjected to the heat treatment. It is supposed that the exposed area ratio of Ag is relatively increased by the concentration and agglomeration of alloy elements which have been distributed over the Ag alloy film, by the heat treatment.

In the foregoing, the present invention is described by means of the embodiments. The present invention, however, is not limited to the embodiments, and it may be modified without deviating from the claims of the present invention, and such modification is within the scope of the present invention.

This application claims priority from Japanese Patent Application No. 2011-285922 filed on Dec. 27, 2011, the disclosure of which is incorporated herein by reference in its entirety.

### INDUSTRIAL APPLICABILITY

According to the present invention, an Ag alloy film having low electrical resistivity and high reflectance that are almost at the same levels as those of an Ag film, and oxidation resistance superior to Ag and existing Ag alloy films is obtained. Therefore, by applying the Ag alloy film of the present invention to a reflective electrode, superior display performance can be attained in the top-emission type OLED display panel as the Ag alloy film shows unique resistance to cleaning treatment such as UV irradiation.

1. An Ag alloy thin film, comprising;
at least one element selected from the group consisting of In and Zn in an amount of from 0.1 to 2.0 atomic %.

2. The Ag alloy thin film according to claim 1, further comprising Bi in an amount of from 0.01 to 1.0 atomic % with the proviso that a Ag—Zn—Bi alloy film which comprises only Zn and satisfies expression (1) is excluded:
7×[A]+13×[Bi]≧8 (1),
wherein
[A] is a content of Zn in atomic % and [Bi] is a content of Bi in atomic %.

3. A reflective electrode comprising;
the Ag alloy film according to claim 1, and
a transparent conductive film consisting of ITO or IZO,
wherein the transparent conductive film is formed in a thickness range of from 5 to 20 nm directly above the Ag alloy film.

4. A method for forming the Ag alloy film according to claim 1, comprising depositing the Ag alloy film by sputtering with an Ag alloy sputtering target,
wherein the sputtering target comprises at least one element selected from the group consisting of In and Zn in an amount of from 0.1 to 2.0 atomic %.

5. The method according to claim 4, wherein the sputtering target further comprises Bi in an amount of from 0.01 to 1.0 atomic %,
with the proviso that a Ag—Zn—Bi alloy sputtering target which comprises only Zn and satisfies expression (1) is excluded:
7×[A]+13×[Bi]≧8 (1),
wherein
[A] denotes is a content of Zn in atomic % and [Bi] is a content of Bi in atomic %.

6. A liquid crystal display device comprising the reflective electrode according to claim 3.

7. An organic EL display device or an organic EL lighting device, comprising the reflective electrode according to claim 3.

8. An inorganic EL display device or an inorganic EL lighting device, comprising the reflective electrode according to claim 3.

9. A touch panel device, comprising the reflective electrode according to claim 3.

10. A projection display device, comprising the reflective electrode according to claim 3.

11. A LED device comprising, the reflective electrode according to claim 3.

12. The Ag alloy thin film according to claim 1, comprising In in an amount of from 0.1 to 2.0 atomic %.

13. The Ag alloy thin film according to claim 1, comprising Zn in an amount of from 0.1 to 2.0 atomic %.

14. The Ag alloy thin film according to claim 1, comprising In and Zn in an amount of from 0.1 to 2.0 atomic %.

15. The Ag alloy thin film according to claim 1, comprising at least one element selected from the group consisting of In and Zn in an amount of from 0.3 to 1.5 atomic %.

16. The Ag alloy thin film according to claim 1, comprising at least one element selected from the group consisting of In and Zn in an amount of from 0.5 to 1.3 atomic %.

17. The Ag alloy thin film according to claim 1, further comprising Bi in an amount of from 0.05 to 0.8 atomic %.

18. The Ag alloy thin film according to claim 1, further comprising Bi in an amount of from 0.05 to 0.5 atomic %.

19. The Ag alloy thin film according to claim 1, wherein a thickness of the Ag alloy film is from 30 to 200 nm.

20. The Ag alloy film according to claim 1, wherein the film is deposited on a reflective electrode.
